(19) United States
(12) Patent Application Publication
(10) Pub. No.: US 2024/0138111 A1
(43) Pub. Date: Apr. 25, 2024

(54) IMMERSION COOLING APPARATUS AND MANUFACTURING METHOD OF THE SAME

(71) Applicant: Formerica Optoelectronics, Inc., Hsinchu County (TW)

(72) Inventors: Joseph Chen-Kwo Liu, Hsinchu County (TW); Peter Sin-Te Liu, Hsinchu County (TW); Chih-Chun CHIANG, Hsinchu County (TW)

(73) Assignee: Formerica Optoelectronics, Inc., Hsinchu County (TW)

(21) Appl. No.: 18/493,070

(22) Filed: Oct. 23, 2023

Related U.S. Application Data
(60) Provisional application No. 63/418,655, filed on Oct. 24, 2022.

(51) Int. Cl. H05K 7/20

(52) U.S. Cl. CPC H05K 7/20272; H05K 7/20236; G08B 21/18

(57) ABSTRACT

The immersion cooling apparatus includes a cooling tank having a cooling liquid; a cable having a first end and a second end and a protection tube wrapping the cable. The first end connects a first connector, and the second end connects a second connector. At least one of the first end and the second end is located in the cooling tank. The protection tube is configured to separate the cable and the cooling liquid, and the protection tube includes at least one of a hard tube, a soft tube, or a thermal shrinking tube.

### CROSS-REFERENCE TO RELATED APPLICATION

This application claims priority to U.S. Provisional Application Ser. No. 63/418,655, filed Oct. 24, 2022, which is herein incorporated by reference in its entirety.

### BACKGROUND

### Field of Invention

The present invention relates to an immersion cooling apparatus and manufacturing method.

### Description of Related Art

In the immersion cooling of the liquid cooling technology field, a server or an electronic component is directly immersed in an non-conducting cooling liquid, and the heat produced by the server or the electronic component can be transferred to the cooling liquid.

However, the jacket of the cable is corroded due to the property difference between the cooling liquid of the immersion cooling apparatus and the jacket of the cable. The cooling liquid may crawl along the cable over the cooling tank, and therefore the connecting effect will be influenced.

Accordingly, it is still a development direction for the industry to provide an immersion cooling apparatus that can solve the problems mentioned above.

### SUMMARY

One aspect of the present invention is an immersion cooling apparatus. The immersion cooling apparatus includes a cooling tank having a cooling liquid; a cable having a first end and a second end and a protection tube wrapping the cable. The first end connects a first connector, and the second end connects a second connector. At least one of the first end and the second end is located in the cooling tank. The protection tube is configured to separate the cable and the cooling liquid, and the protection tube includes at least one of a hard tube, a soft tube, or a thermal shrinking tube.

Another aspect of the present invention is an immersion cooling apparatus. The immersion cooling apparatus includes a cooling tank having a cooling liquid, a cable having a first end and a second end, and at least one stopper surrounding and in contact with the cable. The first end connects a first connector, and the second end connects a second connector. At least one of the first end and the second end is located in the cooling tank. The stopper is configured to block the cooling liquid.

Another aspect of the present invention is an manufacturing method of an immersion cooling apparatus, which includes jacketing the cable with a protection tube outside; connecting two ends of the protection tube and warps the first end and the second end of the cable through the first connector and the second connector, respectively; and putting at least one of the first end and the second end of the cable into the cooling tank.

Another aspect of the present invention is an manufacturing method of an immersion cooling apparatus, which includes mounting a stopper around the cable, and the stopper surrounds and contacts the cable; and putting at least one of the first end and the second end of the cable into the cooling tank.

In the aforementioned embodiments, a stopper can be disposed outside the cable of the immersion cooling apparatus to separate the cable and the cooling liquid. The stopper includes protection tube, elastic tube, or 0-rings. The stopper can block the cooling liquid to stop the cooling liquid from crawling on the cable. Therefore, the stopper can prevent the jacket of the cable from being corroded, and prevent the cooling liquid crawling to the connector from affecting the connecting ability between two cables or between the cable and the electronic element.

### BRIEF DESCRIPTION OF THE DRAWINGS

The invention can be more fully understood by reading the following detailed description of the embodiment, with reference made to the accompanying drawings as follows:

FIG. 1 is a schematic of an immersion cooling apparatus according to one embodiment of the present disclosure.

FIG. 2 is a schematic of an immersion cooling apparatus according to another embodiment of the present disclosure.

FIG. 3 is a schematic of a cable and a protection tube according to another embodiment of the present disclosure.

FIG. 4 is a partial perspective view of a cable and a protection tube according to another embodiment of the present disclosure.

FIG. 5A is a schematic of a cable and an elastic tube according to one embodiment of the present disclosure.

FIG. 5B is a schematic of a cable and an elastic tube according to another embodiment of the present disclosure.

FIG. 6A is a schematic of an elastic tube according to one embodiment of the present disclosure when the first component and the second component are separated.

FIG. 6B is a schematic of the elastic tube in FIG. 6A when the first component is mounted with the second component.

FIG. 6C is a schematic of the elastic tube in FIG. 6A when the first component is expanded.

FIG. 7A is a cross-sectional view of a cable and an elastic tube according to one embodiment of the present embodiment.

FIG. 7B is a cross-sectional view of a cable and an elastic tube according to another embodiment of the present disclosure.

FIG. 8A is a schematic of a combination of a cable and an elastic tube according to one embodiment of the present embodiment.

FIG. 8B is a stereoscopic view of the elastic tube in FIG. 8A.

FIG. 9A to FIG. 9C are schematics of the cables and the elastic tubes according to different embodiments of the present disclosure.

FIG. 10A to FIG. 10C are schematics of the cables and the O-rings according to different embodiments of the present disclosure.

FIG. 11 is a schematic of a combination of a cable and an elastic tube according to one embodiment of the present embodiment.

FIG. 12 is a schematic of a extender port according to one embodiment of the present embodiment.

FIG. 13A to FIG. 13C are manufacturing methods of an elastic tube according to one embodiment of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

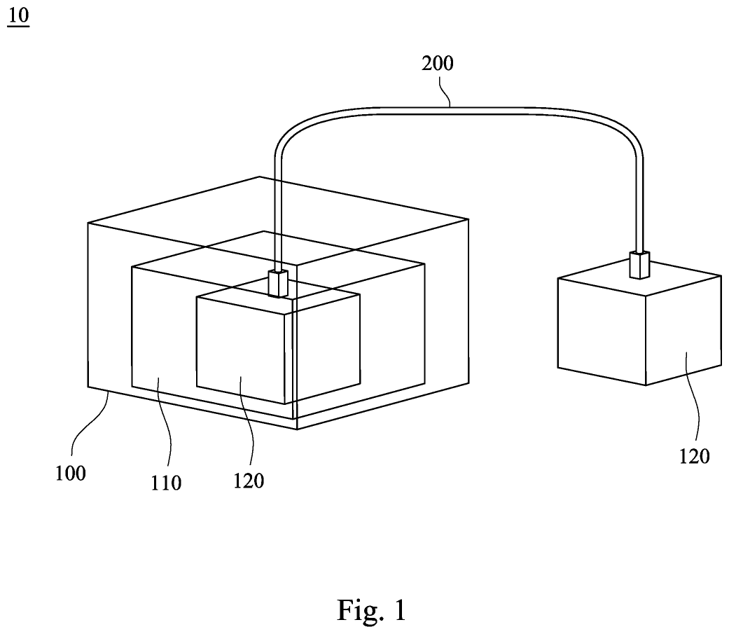

FIG. 1 is a schematic of an immersion cooling apparatus 10 according to one embodiment of the present disclosure. The immersion cooling apparatus 10 includes a cooling tank 100 and a cable 200. The cooling tank 100 carries a mount of cooling liquid 110 and an electronic component 120. The electronic component 120 can be server or switch that configured to connect the cable 200. The electronic component 120 is immersed in the cooling liquid 110 such that the heat can be transferred to the cooling liquid 110. Two ends of the cable 200 respectively connect the electronic component 120 in the cooling tank 100 and another electronic component 120 not located in the cooling tank 100.

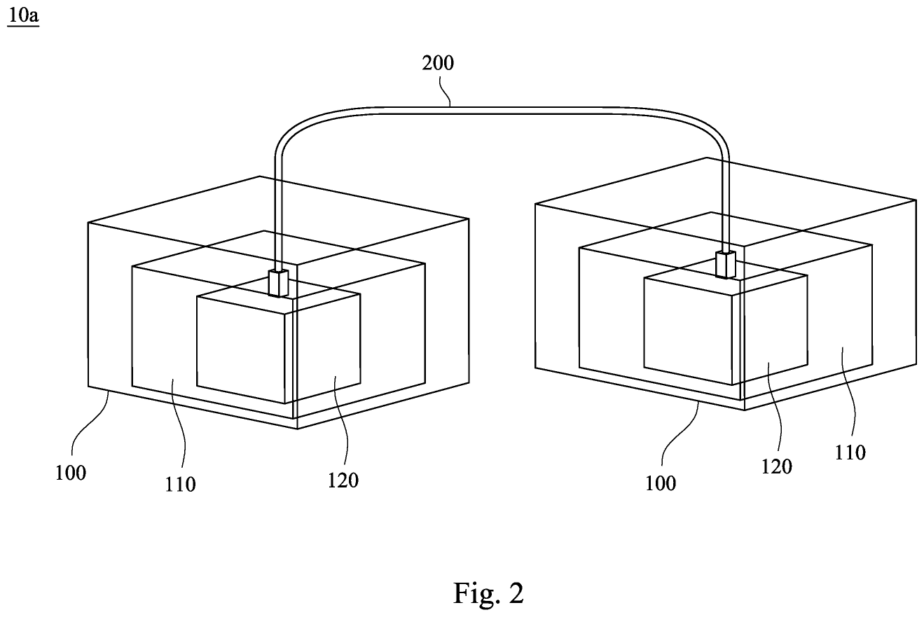

FIG. 2 is a schematic of an immersion cooling apparatus 10a according to another embodiment of the present disclosure. The difference between the immersion cooling apparatus 10a and the immersion cooling apparatus 10 is that the immersion cooling apparatus 10a includes two cooling tanks 100, and the two ends of the cable 200 respectively connect the electronic components 120 in these two cooling tanks 100.

A stopper can be disposed outside the cable 200 to separate the cable 200 and the cooling liquid 110. The stopper can include hermetic protection tube, elastic tube segments, or O-rings, which will be described in detail. The stopper can block the cooling liquid to stop the cooling liquid from crawling on the cable 200, prevent the jacket of the cable 200 from being corroded, prevent the cooling liquid 110 crawling to the connector from affecting the connecting effect between two cables 200 or between the cable 200 and the electronic component 120, and reduce the consumption of cooling liquid 110.

In the present embodiment, the cable 200 can be an Active Optical Cable (AOC), a Direct Attach Cable (DAC), and an extender port connecting with an AOC or a DAC.

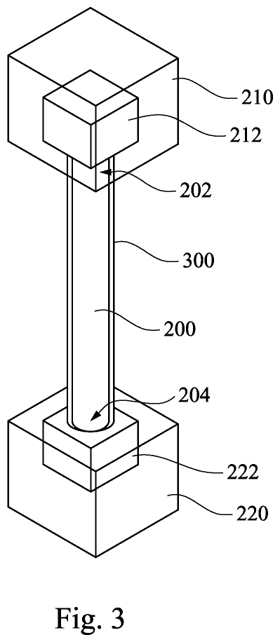

FIG. 3 is a schematic of a cable 200 and a protection tube 300 according to another embodiment of the present disclosure. The cable 200 includes a first end 202 and a second end 204. The first end 202 connects a first connector 210, the second end 204 connects a second connector 220. The first connector 210 includes a first inner mold 212, the second connector 220 includes a second inner mold 222. As shown in FIG. 1 and FIG. 2, at least one of the first end 202 and the second end 204 is located in the cooling tank 100.

In some embodiments, the first connector 210 and the second connector 220 connecting with an Active Optical Cable includes Small Form-Factor Pluggable (SFP) series transceiver module, Quad Small Form-factor Pluggable (QSFP) transceiver module, QSFP112, Quad Small Form Pluggable Double Density (QSFP-DD), or Octal Small Form Factor Pluggable (OSFP), but the present disclosure is not limited thereto. In some other embodiments, one of the first connector 210 and the second connector 220 is a Multi-fiber Pull Off (MPO) connector.

The protection tube 300 wraps the cable 200 to separate the cable 200 and the cooling liquid 110 (see FIG. 1). The protection tube 300 is a hermetic tube used as a cooling liquid anti-corrosion tube, and it can include at least one of a hard tube, a soft tube, or a thermal shrinking tube. The protection tube 300 includes silicon, rubber, Teflon (Polytetrafluoroethylene, PTFE) based material, or a combination thereof. The present disclosure is not limited thereto. The material of the protection tube 300 can be adjusted based on the cooling liquid 110 used and using scenario.

In the embodiment shown in FIG. 3, the first connector 210 and the second connector 220 wraps two ends of the protection tube 300 to form a hermetic tube, but the present disclosure is not limited thereto. In other embodiment, the protection tube 300 can warps the first connector 210 and/or the second connector 220 as long as the two ends of the protection tube 300 are sealed.

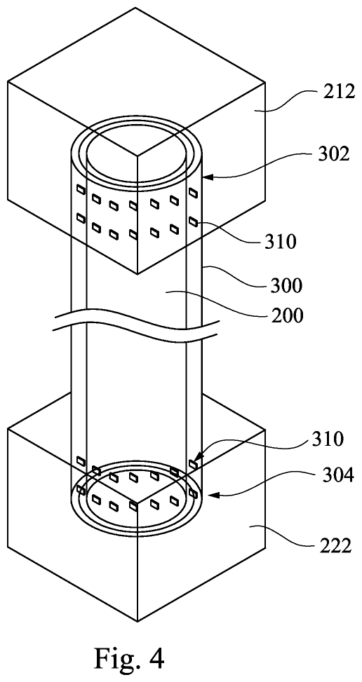

FIG. 4 is a partial perspective view of a cable 200 and a protection tube 300 according to another embodiment of the present disclosure. The protection tube 300 in this embodiment is a thermal shrinking tube. Two ends 302, 304 of the protection tube 300 include multiple holes 310. The holes 310 are clamped in the first inner mold 212 and the second inner mold 222 such that the two ends of the protection tube 300 are wrapped and sealed. When adhering the first inner mold 212 and the second inner mold 222 to the cable 200, the holes 310 makes the adhesive flow and fully fill into the gaps between the protection tube 300 and the cable 200 and between the protection tube 300 and the first inner mold 212 and the second inner mold 222. As such, sealing efficiency of the protection tube 300 is enhanced.

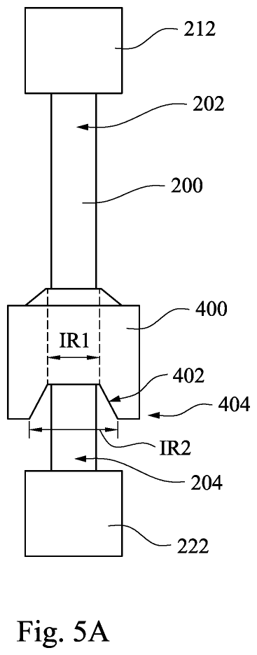

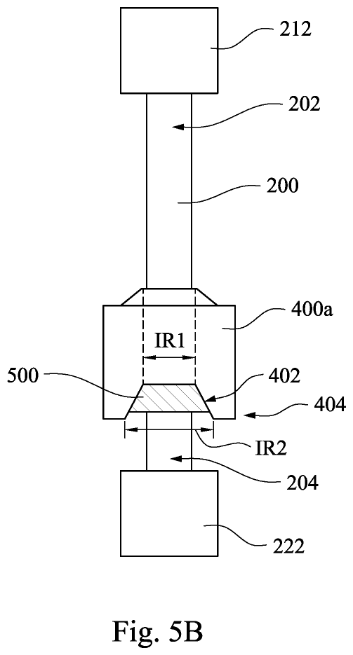

FIG. 5A is a schematic of a cable 200 and an elastic tube 400 according to one embodiment of the present disclosure. The elastic tube 400 surrounds the cable 200. In other embodiment, the elastic tube 400 surrounds the cable 200 wrapped by the protection tube 300. The elastic tube 400 has an inner wall 402. The inner wall 402 has a first inner diameter IR1. The first inner diameter IR1 is slightly greater than or equals the diameter of the cable 200 or the diameter of the cable 200 wrapped by the protection tube 300. The elastic tube 400 can be shifted to a specific position on the cable 200 as a stopper to block the cooling liquid 110 (see FIG. 1) crawling along the cable 200. The elastic tube 400 includes silicon, rubber, Teflon (PTFE) based material, or a combination thereof. The present disclosure is not limited thereto.

The elastic tube 400 has a second inner diameter IR2. The second inner diameter IR2 is greater than the first inner diameter IR1. The second inner diameter IR2 is located at an end 404 of the elastic tube 400. Therefore, a difference between the first inner diameter IR1 and the second inner diameter IR2 makes the inner wall 402 of the elastic tube 400 forms an inclined surface having a bell shape, a fan shape, or an umbrella shape. Such structural design of the elastic tube 400 is a V-ring.

With such design, the cooling liquid 110 crawling on the cable 200 cannot go across the inclined surface of the inner wall 402 and continuously reach another side of the cable 200. For example, when the cooling liquid 110 crawls from the second end 204 of the cable 200 upward towards the position corresponding to the first inner diameter IR1 of inner wall 402, the surface tension between the cooling liquid 110 and the inclined inner wall 402 is greater than the adhesive force between the cooling liquid 110 and the cable 200 (or the protection tube 300). The cooling liquid 110 gradually falls due to gravity, and therefore it is difficult for the cooling liquid 110 to go across the inner wall 402 and crawls towards the first end 202 of the cable 200 over the outer surface of the elastic tube 400.

FIG. 5B is a schematic of a cable 200 and an elastic tube 400a according to another embodiment of the present disclosure. The difference between the elastic tube 400a and the elastic tube 400 is that the elastic tube 400a further includes a sealant 500 configured to fix the position of the elastic tube 400 relative to the cable 200. The sealant 500 of the present disclosure is located at the end 404 of the elastic tube 400, but the present disclosure is not limited thereto. The sealant 500 can be merely located at a gap between the elastic tube 400 and the cable 200 (or the protection tube 300), or partially or completely filled in the space between the inner wall 402 and the cable 200. The inclined surface formed by the inner wall 402 can still stop the cooling liquid from crawling on the cable 200. In other embodiment, the sealant 500 is disposed between the inner wall 402 and the cable 200 and fully fills the space between the inner wall 402 and the cable 200.

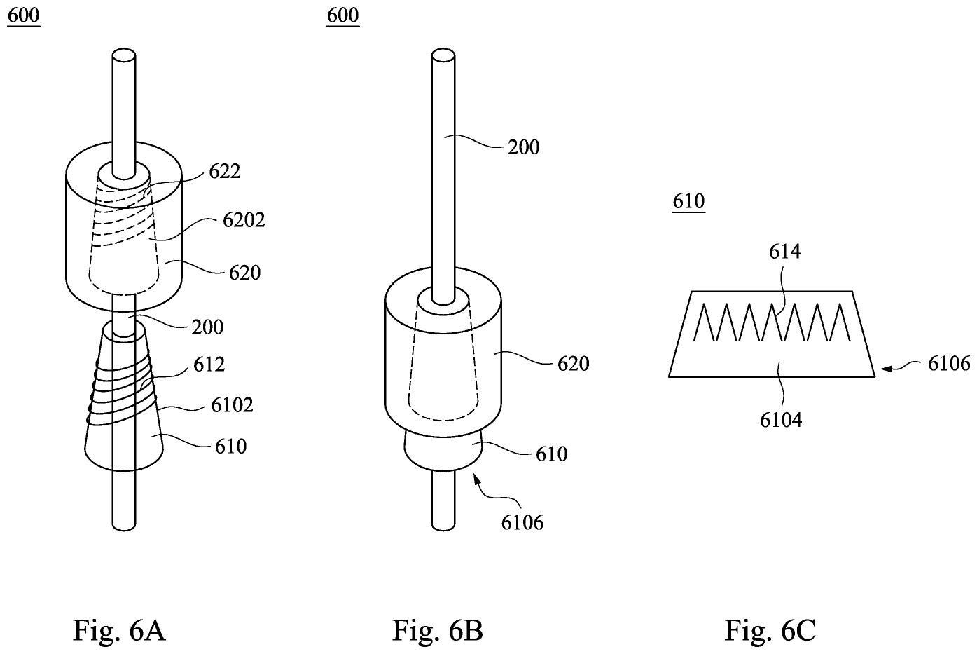

FIG. 6A is a schematic of an elastic tube 600 according to one embodiment of the present disclosure when the first component and the second component are separated. The elastic tube 600 includes a first component 610 and a second component 620. The first component 610 has an outer screw thread 612 on an outer wall 6102, the second component 620 has an inner screw thread 622 on an inner wall 6202. The first component 610 is configured to connect the second component 620 detachably. The first component 610 has cone shape. One end facing the second component 620 has a smaller diameter, and the other end away from the second component 620 has a greater diameter.

FIG. 6B is a schematic of the elastic tube 600 in FIG. 6A when the first component 610 is mounted with the second component 620. The first component 610 and the second component 620 can be freely shifted on the cable 200 before screwed together. The elastic tube 600 surrounds the cable 200. In other embodiment, the elastic tube 600 surrounds the cable warps by the protection tube 300. The first component 610 and the second component 620 screwed together can be used as a stopper that stops the cooling liquid from crawling on the cable 200. Since the first component 610 has a cone shape and is elastic, the inner wall 6202 of the second component 620 can squeeze the cone-shaped first component 610 to fix the entire elastic tube 600 on the cable 200 and makes the first component 610 engages firmly with the second component 620 when the screw depth therebetween is increased. The inner wall 6202 of the second component 620 has a cone shape. In other embodiment, the inner wall 6202 of the second component 620 has a cylindrical shape (not shown), and the screw depth between the first component 610 and the second component 620 is shallower.

FIG. 6C is a schematic of the elastic tube 600 in FIG. 6A when the first component 610 is expanded. The inner wall 6104 of the first component 610 has a zigzag structure 614. The zigzag structure 614 makes the interval between the inner wall 6104 of the first component 610 and the cable 200 at the end 6106 greater. Such design can be considered as that the inner wall 6104 has multiple inclined surfaces shown in FIG. 5B, and therefore the cooling liquid 110 crawling on the cable 200 cannot go across the inclined surface of the inner wall 6104 and continuously reach another side of the cable 200.

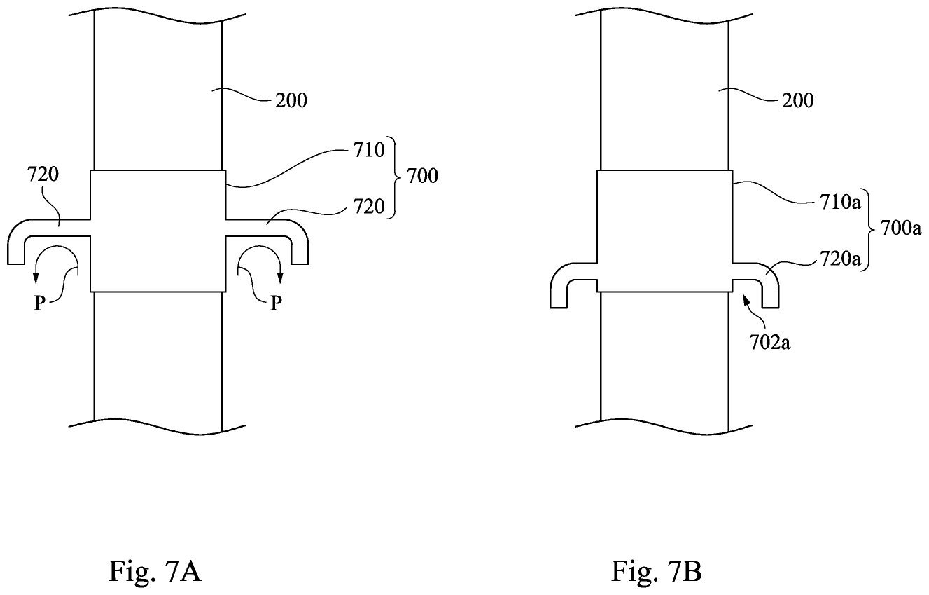

FIG. 7A is a cross-sectional view of a cable 200 and an elastic tube 700 according to one embodiment of the present embodiment. The elastic tube 700 surrounds the cable 200. In other embodiment, the elastic tube 700 surrounds the cable 200 wraps by the protection tube 300. The elastic tube 700 has a cylindrical shape and has an outer surface 710 and a branch 720 extending from the outer surface 710. The elastic tube 700 can be shifted to a specific position on the cable 200 as a stopper to block the cooling liquid 110 (see FIG. 1) crawling along the cable 200. The branch 720 forms a ring structure having a bell shape, a fan shape, or an umbrella shape, and therefore the cooling liquid 110 crawling on the cable 200 cannot go across the branch 720 and continuously reach another side of the cable 200. For example, the path P in FIG. 7A shows a way the cooling liquid 110 flows. The cooling liquid 110 crawls along the outer surface 710 to the branch 720, and then flows along the branch 720 to fall.

FIG. 7B is a cross-sectional view of a cable 200 and an elastic tube 700a according to another embodiment of the present disclosure. The elastic tube 700a has an outer surface 710a and a branch 720a extending from the outer surface 710a. The branch 720a is located at an end 702a of the elastic tube 700a. The elastic tube 700a and the elastic tube 700 have the same advantages, and therefore the description is not repeated.

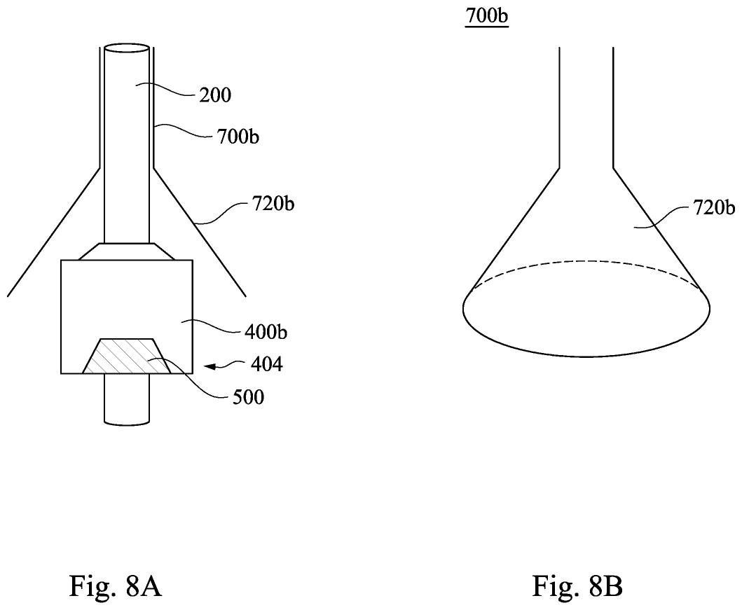

FIG. 8A is a schematic of a combination of a cable 200 and an elastic tube according to one embodiment of the present embodiment. The present embodiment includes a elastic tube 400b fixed on the cable 200 and an umbellar-shaped elastic tube 700b. FIG. 8B is a stereoscopic view of the elastic tube 700b in FIG. 8A. The branch 720b of the elastic tube 700b forms a ring structure having a bell shape, a fan shape, or an umbrella shape.

The elastic tube 700b is disposed above the elastic tube 400b. The position of the elastic tube 700b can be fixed on the cable 200 through the elastic tube 400b. In the present embodiment, the end 404 of the elastic tube 400b is level with the sealant 500. In other embodiment, the elastic tube 700b can be disposed below the elastic tube 400b, such that the elastic tube 700b can pass through the end 404 of the elastic tube 400b (not shown). If the cooling liquid 110 flows over the elastic tube 400b, the branch 720b of the elastic tube 700b can stop the cooling liquid 110 from continuously crawling. In other embodiment, the elastic tube 400a shown in FIG. 5B can be used herein, and the elastic tube 400a and the elastic tube 700b both can stop the cooling liquid 110 from crawling. The positions of the elastic tube 400a and the elastic tube 700b can be determined based on practical requirement, which are not limited as the configurations shown in this embodiment.

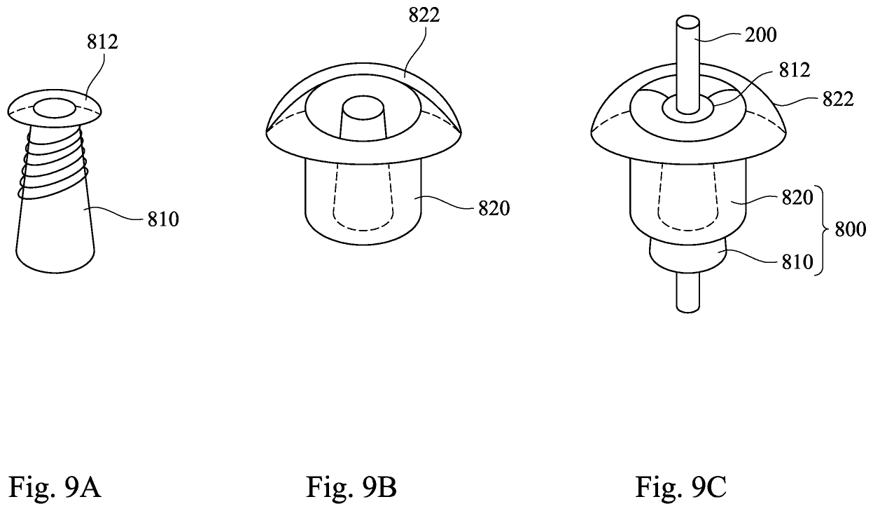

FIG. 9A to FIG. 9C are schematics of the cables 200 and the elastic tubes 800 according to different embodiments of the present disclosure. As shown in FIG. 9C, the elastic tube 800 includes a first component 810 (FIG. 9A) and a second component 820 (FIG. 9B) similar to FIG. 6A. The difference is that the first component 810 includes a branch 812 having an umbrella shape, and the second component 820 includes a branch 822 having an umbrella shape. The branch 812 extends from the top of the first component 810. The branch 822 extends from the top of the second component 820.

The branch 812 of the first component 810 and the branch 822 of the second component 820 can be made from thinner and softer material, such that the branch 812 of the first component 810 can pass through the gap between the second component 820 and the cable 200. With such design, mounted elastic tube 800 can block the cooling liquid 110 through the zigzag structure 614 (see FIG. 6C) of the first component 810, and enhance the ability to stop the cooling liquid 110 from crawling through the branch 812 and the branch 822.

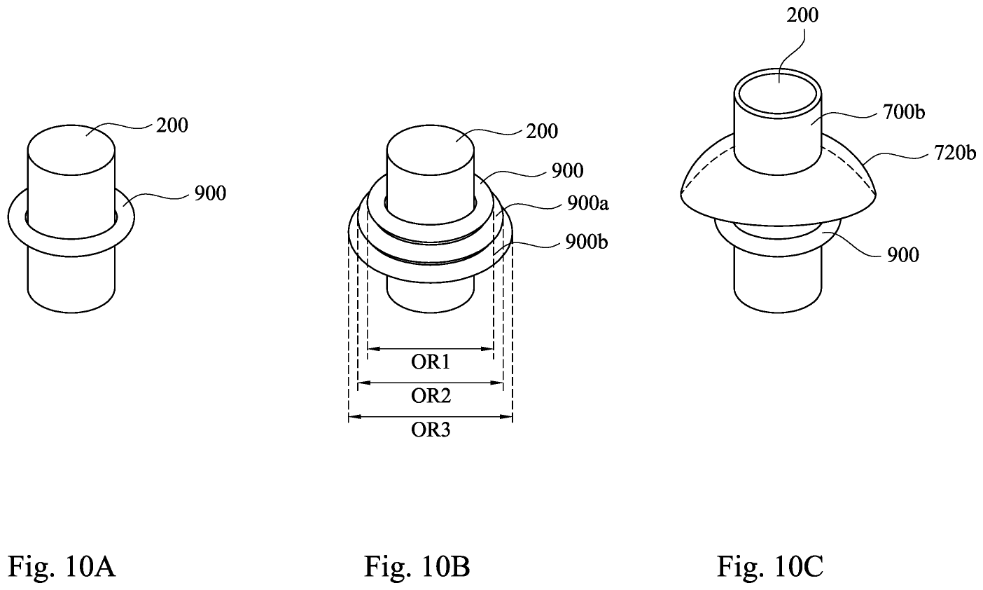

FIG. 10A to FIG. 10C are schematics of the cables 200 and the O-rings according to different embodiments of the present disclosure. The O-ring 900 in FIG. 10A surrounds the cable 200. In other embodiment, the O-ring 900 surrounds the cable 200 wrapped by the protection tube 300. The O-ring 900 is used as a stopper to stop the cooling liquid from crawling on the cable 200. The O-rings 900, 900a, 900b are included in FIG. 10B, and theses O-rings have the same inner diameter and different outer diameter. The O-rings 900, 900a, 900b respectively have a first outer diameter OR1, a second outer diameter OR2, and a third outer diameter OR3. The O-ring 900a is located between the O-ring 900 and the O-ring 900b. The third outer diameter OR3 is greater than the second outer diameter OR2, and the second outer diameter OR2 is greater than the first outer diameter OR1. In other words, three O-rings 900, 900a, 900b form a mushroom shape structure to enhance the ability of blocking the cooling liquid between the O-rings and the cable. An O-ring 900 and the elastic tube 700b shown in FIG. 8A are included in FIG. 10C. In the present embodiment, the O-ring 900 and the branch 720b of the elastic tube 700b can stop the cooling liquid.

When the protection tube 300 is disposed between the elastic tube and the cable 200, the manufacturing method of the immersion apparatus 10 is firstly to jacket the cable 200 with the protection tube 300 outside, and then mount at least one elastic tube or at least one O-ring around the protection tube 300. Subsequently, connecting the two ends of the protection tube 300 and warps the first end 202 and the second end 204 of the cable 200 through the first connector 210 and the second connector 220. Lastly, put at least one of the first end 202 and the second end 204 of the cable 200 into the cooling tank 100.

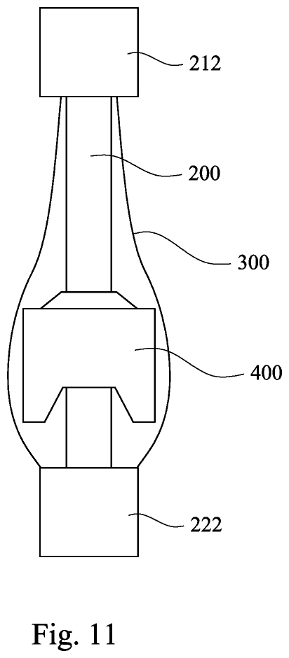

FIG. 11 is a schematic of a combination of a cable 200 and an elastic tube according to one embodiment of the present embodiment. The present embodiment includes an elastic tube 400 fixed on the cable 200 and a protection tube 300 warps the elastic tube 400. The elastic tube 400 can blocks the cooling liquid, and the protection tube 300 can prevent the cable 200 and the elastic tube 400 from being corroded by the cooling liquid. In other embodiment, the elastic tube 400 can be a combination of various elastic tubes described in FIG. 5B to FIG. 10C.

When the elastic tube is disposed between the protection tube 300 and the cable 200, the manufacturing method of the immersion apparatus 10 is firstly mount the elastic tube around the cable 200, such that the elastic tube surrounds and contacts the cable 200. The elastic tube is mounted on the cable 200 from one of the first end 202 and the second end 204. Subsequently, jacketing the cable 200 and the elastic tube with the protection tube 300, and connecting the two ends of the protection tube 300 through the first connector 210 and the second connector 220. Lastly, put at least one of the first end 202 and the second end 204 of the cable 200 into the cooling tank 100.

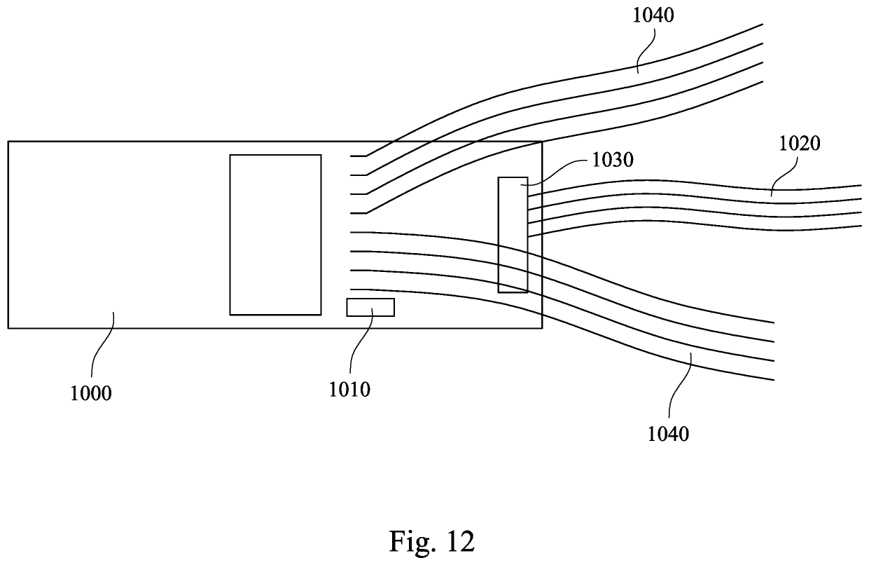

FIG. 12 is a schematic of an extender port according to one embodiment of the present embodiment. Reference is made to FIG. 1 and FIG. 12. When the cable 200 is an extender port, another cable 200 such as a DAC is connected. A connector 1000 connecting the extender port and the DAC is illustrated in FIG. 12. The connector 1000 can be disposed in the cooling liquid 110 or outside the cooling liquid 110. The connector 1000 includes a light-emitting diode 1010, a low speed transmission wire 1020, a side band connector 1030, and a high speed transmission wire 1040.

The side band connector 1030 connects the low speed transmission wire 1020 and the light-emitting diode 1010. When the extender port and the DAC are not connected properly, the light-emitting diode 1010 irradiates and set the alarm, which is beneficial to monitoring connecting situation. When the connector 1000 is in the cooling liquid 110, the signal form the light-emitting diode 1010 is beneficial for recognizing the position of the connector which is not connected properly.

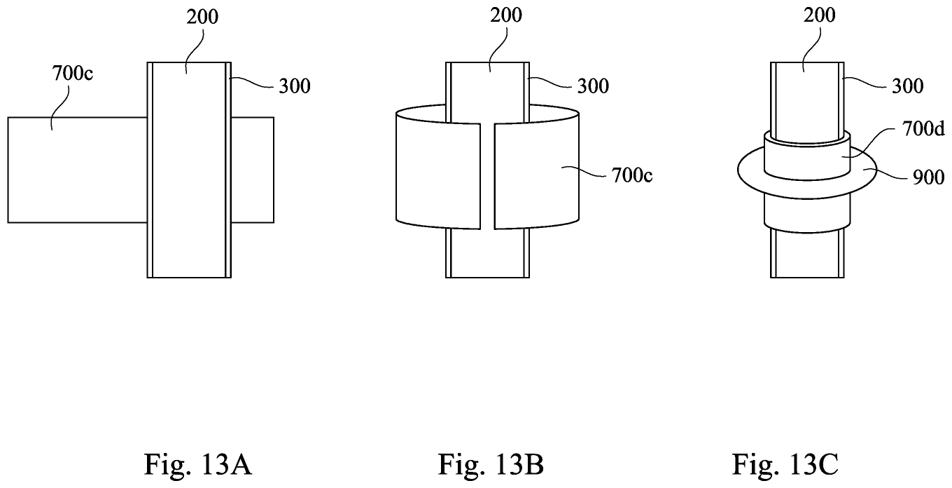

FIG. 13A to FIG. 13C are manufacturing methods of an elastic tube according to one embodiment of the present disclosure. In the present embodiment, the O-ring 900 can be mounted onto the cable 200 first, and then connecting the cable 200 with the first connector 210 and the second connector 220 (see FIG. 3). The protection tube 300 is mounted on the cable 200 first herein, but the present disclosure is not limited thereto.

As shown in FIG. 13A and FIG. 13B, surround the cable 200 with an elastic material sheet 700c such that the elastic material sheet 700c has a ring-shape. As shown in FIG. 13C, mount the O-ring 900 on onto the elastic material sheet 700c such that the elastic material sheet 700c forms the elastic tube 700d. Such method can increase the flexibility to dispose the elastic tube and enable the users to add elastic tube or O-ring depends on the requirement in the using process.

In summary, a stopper can be disposed outside the cable of the immersion cooling apparatus to separate the cable and the cooling liquid. The stopper includes protection tube, elastic tube, or O-rings. The stopper can block the cooling liquid to stop the cooling liquid from crawling on the cable. Therefore, the stopper can prevent the jacket of the cable from being corroded, and prevent the cooling liquid crawling to the connector from affecting the connecting effect between two cables or between the cable and the electronic element.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An immersion cooling apparatus, comprising:
a cooling tank comprising a cooling liquid;
a cable comprising a first end and a second end, wherein the first end connects a first connector, the second end connects a second connector, at least one of the first end and the second end is located in the cooling tank; and
a protection tube wrapping the cable, wherein the protection tube is configured to separate the cable and the cooling liquid, and the protection tube comprises at least one of a hard tube, a soft tube, or a thermal shrinking tube.

2. The immersion cooling apparatus of claim 1, wherein the first connector comprises a first inner mold, the second connector comprises a second inner mold, two ends of the protection tube comprise a plurality of holes, and the holes are clamped in the first inner mold of the first connector and the second inner mold of the second connector.

3. The immersion cooling apparatus of claim 1, further comprising:
an elastic tube surrounding the cable or the protection tube.

4. The immersion cooling apparatus of claim 3, wherein the elastic tube has an inner wall, the inner wall has a first inner diameter and a second inner diameter, the second inner diameter is greater than the first inner diameter, and the second inner diameter is located at an end of the elastic tube.

5. The immersion cooling apparatus of claim 3, wherein the elastic tube further comprises a sealant configured to adhere the elastic tube.

6. The immersion cooling apparatus of claim 3, wherein the elastic tube comprises a first component and a second component, the first component has an outer screw thread, the second component has an inner screw thread, the first component is configured to connect the second component detachably.

7. The immersion cooling apparatus of claim 4, wherein the inner wall of the elastic tube comprises a zigzag structure.

8. The immersion cooling apparatus of claim 3, wherein the elastic tube has an outer surface and a branch extending from the outer surface.

9. The immersion cooling apparatus of claim 1, further comprising:
an O-ring surrounding the cable or the protection tube.

10. The immersion cooling apparatus of claim 1, further comprising:
a plurality of O-rings surrounding the cable or the protection tube, wherein the O-rings have the same inner diameter and different outer diameter.

11. The immersion cooling apparatus of claim 1, further comprising:
a light-emitting diode disposed on one of the first connector and the second connector.

12. An immersion cooling apparatus, comprising:
a cooling tank comprising a cooling liquid;
a cable comprising a first end and a second end, wherein the first end connects a first connector, the second end connects a second connector, at least one of the first end and the second end is located in the cooling tank; and
at least one stopper surrounding and in contact with the cable, wherein the stopper is configured to block the cooling liquid.

13. The immersion cooling apparatus of claim 12, wherein the stopper comprises an elastic tube, the elastic tube has an inner wall, the inner wall has a first inner diameter and a second inner diameter, the second inner diameter is greater than the first inner diameter, and the second inner diameter is located at an end of the elastic tube.

14. The immersion cooling apparatus of claim 13, wherein the elastic tube further comprises a sealant filled in a gap between the elastic tube and the cable.

15. The immersion cooling apparatus of claim 13, wherein the elastic tube comprises a first component and a second component, the first component has an outer screw thread, the second component has an inner screw thread, the first component is configured to connect the second component detachably.

16. The immersion cooling apparatus of claim 13, wherein the inner wall of the elastic tube comprises a zigzag structure.

17. The immersion cooling apparatus of claim 12, wherein the stopper has an outer surface and a branch extending from the outer surface.

18. The immersion cooling apparatus of claim 12, wherein the stopper comprises an O-ring.

19. The immersion cooling apparatus of claim 12, wherein the stopper comprises a plurality of O-rings, the O-rings have the same inner diameter and different outer diameter.

20. The immersion cooling apparatus of claim 12, further comprising:
a protection tube surrounding the cable, wherein the first connector and the second connector connect two ends of the protection tube, and the protection tube is configured to separate the cable and the cooling liquid.

21. The immersion cooling apparatus of claim 12, further comprising:
a light-emitting diode disposed on one of the first connector and the second connector.

22. A manufacturing method of an immersion cooling apparatus, comprising:
jacketing a cable with a protection tube outside;
connecting two ends of the protection tube and warps a first end and a second end of the cable through a first connector and a second connector, respectively; and
putting at least one of the first end and the second end of the cable into a cooling tank

23. The manufacturing method of the immersion cooling apparatus of claim 22, wherein the protection tube includes a thermal shrinking tube, and connecting the two ends of the protection tube through the first connector and the second connector further comprises:
clamping a plurality of holes on the two ends of the thermal shrinking tube through a first inner mold of the first connector and a second inner mold of the second connector.

24. The manufacturing method of the immersion cooling apparatus of claim 22, further comprising:
mounting at least one elastic tube or at least one O-ring around the protection tube before connecting the two ends of the protection tube through the first connector and the second connector.

25. A manufacturing method of an immersion cooling apparatus, comprising:
mounting a stopper around a cable, wherein the stopper surrounds and contacts the cable; and
putting at least one of a first end and a second end of the cable into a cooling tank.

26. The manufacturing method of the immersion cooling apparatus of claim 25, wherein the stopper is mounted from one of the first end and the second end of the cable.

27. The manufacturing method of the immersion cooling apparatus of claim 25, wherein the stopper is an elastic tube, and mounting the stopper further comprises:
surrounding the cable with an elastic material sheet, such that the elastic material sheet has a ring-shape; and
mounting an O-ring onto the elastic material sheet, such that the elastic material sheet forms the elastic tube.

28. The manufacturing method of the immersion cooling apparatus of claim 25, wherein the stopper is an elastic tube, and mounting the stopper further comprises:
disposing a sealant between the elastic tube and the cable.

29. The manufacturing method of the immersion cooling apparatus of claim 25, wherein the stopper comprises a first component and a second component, the first component has an outer screw thread, the second component has an inner screw thread, and mounting the stopper further comprises:
screwing the first component and the second component, such that the first component connects the second component detachably.

30. The manufacturing method of the immersion cooling apparatus of claim 25, further comprising:
jacketing the cable with a protection tube outside; and
connecting ends of the protection tube through the first connector and the second connector.
